(19) United States
(12) Patent Application Publication
(10) Pub. No.: US 2016/0095215 A1
(43) Pub. Date: Mar. 31, 2016

(54) PRINTED WIRING BOARD AND METHOD FOR MANUFACTURING THE SAME

(71) Applicant: IBIDEN CO., LTD., Ogaki-shi (JP)

(72) Inventor: Toshiki Furutani, Ogaki-shi (JP)

(73) Assignee: IBIDEN CO., LTD., Ogaki-shi (JP)

(21) Appl. No.: 14/865,050

(22) Filed: Sep. 25, 2015

(30) Foreign Application Priority Data
Sep. 25, 2014 (JP) 2014-194726

(51) Int. Cl. H05K 1/09; H05K 3/07; H05K 1/11

(52) U.S. Cl. CPC H05K 1/09; H05K 1/115; H05K 3/07; H05K 2201/09018

(57) ABSTRACT

A printed wiring board includes a resin insulating layer, and a first conductor layer including a fine wiring pattern and a thick-film wiring pattern. The fine wiring pattern is embedded in the resin insulating layer such that the fine wiring pattern has an exposed surface exposed on a first surface of the resin insulating layer. The thick-film wiring pattern includes an embedded wiring portion and a thick-film wiring portion such that the embedded wiring portion is embedded in the resin insulating layer and the thick-film wiring portion is projecting from the first surface of the resin insulating layer. The embedded wiring portion of the thick-film wiring pattern has a line width which is greater than a line width of the fine wiring pattern.

### CROSS-REFERENCE TO RELATED APPLICATIONS

The present application is based upon and claims the benefit of priority to Japanese Patent Application No. 2014-194726, filed Sep. 25, 2014, the entire contents of which are incorporated herein by reference.

### BACKGROUND OF THE INVENTION

1. Field of the Invention

The present invention relates to a printed wiring board that has a conductor circuit pattern in which a fine wiring pattern and a thick-film wiring pattern coexist, and to a method for manufacturing the printed wiring board.

2. Description of Background Art

Japanese Patent Laid-Open Publication No. HEI 10-173316 describes a structure in which a resin film, on which a conductor circuit pattern is formed, is press-bonded to an insulating substrate and thereafter, by peeling off the resin film, the conductor circuit pattern is embedded in a surface of the insulating substrate. The entire contents of this publication are incorporated herein by reference.

### SUMMARY OF THE INVENTION

According one aspect of the present invention, a printed wiring board includes a resin insulating layer, and a first conductor layer including a fine wiring pattern and a thick-film wiring pattern. The fine wiring pattern is embedded in the resin insulating layer such that the fine wiring pattern has an exposed surface exposed on a first surface of the resin insulating layer. The thick-film wiring pattern includes an embedded wiring portion and a thick-film wiring portion such that the embedded wiring portion is embedded in the resin insulating layer and the thick-film wiring portion is projecting from the first surface of the resin insulating layer. The embedded wiring portion of the thick-film wiring pattern has a line width which is greater than a line width of the fine wiring pattern.

According to another aspect of the present invention, a method for manufacturing a printed wiring board includes forming a metal film on a carrier having a carrier metal such that the metal film is formed on the carrier metal, forming a fine wiring pattern and an embedded wiring portion of a thick-film wiring pattern on the metal film, forming a resin insulating layer on the metal film such that the fine wiring pattern and the embedded wiring portion are embedded in the resin insulating layer, removing the carrier from the metal film such that a surface of the metal film is exposed, and etching the metal film such that a portion of the metal film forms a thick-film wiring portion on the embedded wiring portion, the thick-film wiring pattern including the embedded wiring portion and the thick-film wiring portion is formed, and a first conductor layer including the fine wiring pattern and the thick-film wiring pattern is formed. The forming of the fine wiring pattern and the embedded wiring portion includes forming the fine wiring pattern and the embedded wiring portion such that the embedded portion has a line width which is greater than a line width of the fine wiring pattern.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is an explanatory cross-sectional view of a printed wiring board according to an embodiment of the present invention;

FIG. 2A illustrates an example of a positional relation between a thick-film wiring part and an embedded wiring part;

FIG. 2B illustrates another example of a positional relation between a thick-film wiring part and an embedded wiring part;

FIG. 2C illustrates yet another example of a positional relation between a thick-film wiring part and an embedded wiring part;

FIG. 3A is an explanatory cross-sectional view that is exaggeratedly enlarged in a thickness direction for describing a cross-sectional shape of a thick-film wiring part;

FIG. 3B is an explanatory cross-sectional view that is exaggeratedly enlarged in the thickness direction for describing a cross-sectional shape of a thick-film wiring part;

FIG. 4A is an explanatory cross-sectional view for a process of a method for manufacturing the printed wiring board illustrated in FIG. 1;

FIG. 4B is an explanatory cross-sectional view for a process of the method for manufacturing the printed wiring board illustrated in FIG. 1;

FIG. 4C is an explanatory cross-sectional view for a process of the method for manufacturing the printed wiring board illustrated in FIG. 1;

FIG. 4D is an explanatory cross-sectional view for a process of the method for manufacturing the printed wiring board illustrated in FIG. 1;

FIG. 4E is an explanatory cross-sectional view for a process of the method for manufacturing the printed wiring board illustrated in FIG. 1;

FIG. 4F is an explanatory cross-sectional view for a process of the method for manufacturing the printed wiring board illustrated in FIG. 1;

FIG. 4G is an explanatory cross-sectional view for a process of the method for manufacturing the printed wiring board illustrated in FIG. 1;

FIG. 4H is an explanatory cross-sectional view for a process of the method for manufacturing the printed wiring board illustrated in FIG. 1;

FIG. 4I is an explanatory cross-sectional view for a process of the method for manufacturing the printed wiring board illustrated in FIG. 1;

FIG. 4J is an explanatory cross-sectional view for a process of the method for manufacturing the printed wiring board illustrated in FIG. 1;

FIG. 4K is an explanatory cross-sectional view for a process of the method for manufacturing the printed wiring board illustrated in FIG. 1;

FIG. 4L is an explanatory cross-sectional view for a process of the method for manufacturing the printed wiring board illustrated in FIG. 1;

FIG. 4M is an explanatory cross-sectional view for a process of the method for manufacturing the printed wiring board illustrated in FIG. 1;

FIG. 4N is an explanatory cross-sectional view for a process of the method for manufacturing the printed wiring board illustrated in FIG. 1;

FIG. 4O is an explanatory cross-sectional view for a process of the method for manufacturing the printed wiring board illustrated in FIG. 1;

FIG. 4P is an explanatory cross-sectional view for a process of the method for manufacturing the printed wiring board illustrated in FIG. 1;

FIG. 5 is an explanatory cross-sectional view of a printed wiring board according to another embodiment of the present invention;

FIG. 6A is an explanatory cross-sectional view for a process of a method for manufacturing a printed wiring board according to another embodiment of the present invention;

FIG. 6B is an explanatory cross-sectional view for a process of the method for manufacturing the printed wiring board;

FIG. 6C is an explanatory cross-sectional view for a process of the method for manufacturing the printed wiring board; and

FIG. 6D is an explanatory cross-sectional view for a process of the method for manufacturing the printed wiring board.

### DETAILED DESCRIPTION OF THE EMBODIMENTS

The embodiments will now be described with reference to the accompanying drawings, wherein like reference numerals designate corresponding or identical elements throughout the various drawings.

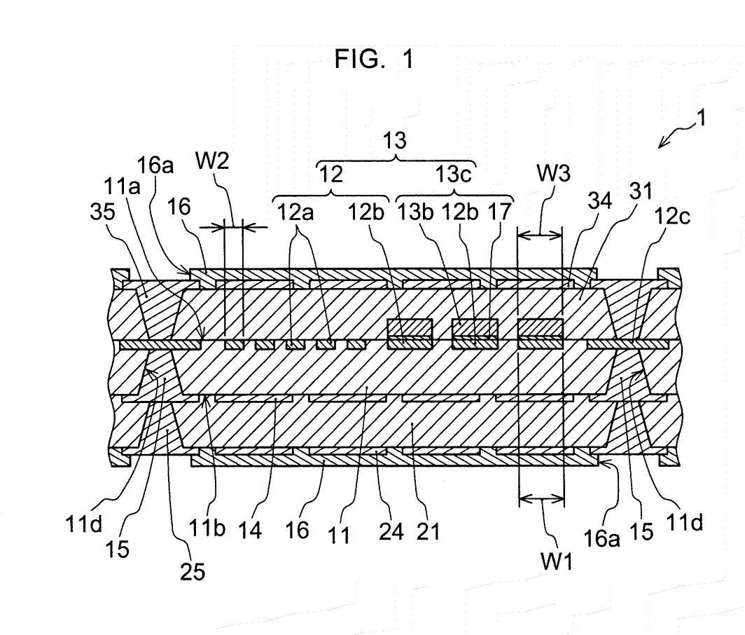

A printed wiring board according to an embodiment of the present invention is described with reference to the drawings. FIG. 1 is an explanatory cross-sectional view of a printed wiring board 1 of the present embodiment. In the printed wiring board 1 of the present embodiment, a first conductor layer 13 is formed in which a fine wiring pattern (12a) and a thick-film wiring pattern (13c) coexist. The fine wiring pattern (12a) is embedded in a first resin insulating layer 11 with only one surface exposed. The first resin insulating layer 11 has a first surface (11a) and a second surface (11b) that is on an opposite side of the first surface (11a). The thick-film wiring pattern (13c) includes an embedded wiring part (12b) and a thick-film wiring part (13b). The embedded wiring part (12b) is embedded in the first resin insulating layer 11. The thick-film wiring part (13b is formed on the embedded wiring part (12b), is electrically connected to the embedded wiring part (12b), and projects from the first resin insulating layer 11. A line width (W1) of the embedded wiring part (12b) of the thick-film wiring pattern (13c) is larger than a line width (W2) of the fine wiring pattern (12a); the fine wiring pattern (12a) and the embedded wiring part (12b) are formed of an electroplating film; and the thick-film wiring part (13b) is formed of a metal foil.

In the example illustrated in FIG. 1, an embodiment is illustrated in which first via conductors 15 are provided in the first resin insulating layer 11; a second conductor layer 14 that is electrically connected to the first conductor layer 13 by the first via conductors 15 is formed on the second surface (11b) side; and further, a second resin insulating layer 21 and a third conductor layer 24 are formed on the second surface (11b) side of the first resin insulating layer 11 and a third resin insulating layer 31 and a fourth conductor layer 34 are formed on the first surface (11a) side of the first resin insulating layer 11, and thus one build-up layer is formed on each of both sides. However, it is also possible that the build-up layer is not formed on any side, but a solder resist layer 16 is formed on each of a surface of the first conductor layer 13 and a surface of the second conductor layer 14; or, the build-up layer is formed on only one of the surfaces; or, two or more build-up layers are formed on each of the surfaces. Further, in the example illustrated in FIG. 1, the line width (W1) of the embedded wiring part (12b) and a line width (W3) of the thick-film wiring part (13b) are illustrated as the same line width. However, the line width (W1) and the line width (W3) may be the same line width or different line widths.

That is, in the printed wiring board 1 of the present embodiment, as illustrated in FIG. 1, the first conductor layer 13 is formed in which the fine wiring pattern (12a) and the thick-film wiring pattern (13c) coexist. The fine wiring pattern (12a) is embedded in the first resin insulating layer 11 and is formed such that only one surface of the fine wiring pattern (12a) is exposed from the first surface (11a) of the first resin insulating layer 11. The fine wiring pattern (12a) is for transmitting, for example, signal data, is formed to have, for example, the line width (W2) of about 3-20 μm, and is formed in a very fine structure having a thickness of about 10-20 μm and an interval of about 3-20 μm. Therefore, as described above, by embedding the fine wiring pattern (12a) in the first resin insulating layer 11, adhesion of the fine wiring pattern (12a) to the first resin insulating layer 11 is ensured and, even when a stress of expansion and contraction due to heat cycles is applied, the fine wiring pattern (12a) is very stably maintained.

The thick-film wiring pattern (13c) includes the embedded wiring part (12b) and the thick-film wiring part (13b). In the example illustrated in FIG. 1, a barrier metal layer 17 is interposed between the two. However, it is also possible that the barrier metal layer 17 is not provided. The barrier metal layer 17 will be described later. The embedded wiring part (12b) is formed simultaneously with the fine wiring pattern (12a) and has the same thickness as the fine wiring pattern (12a). However, the line width (W1) of the embedded wiring part (12b) is about 60-450 μm, which is larger than the line width (W2) of fine wiring pattern (12a). Further, it is also possible that, during the formation, by changing a mask pattern, the embedded wiring part (12b) is formed to also have a thicker thickness than the fine wiring pattern (12a). This is to allow a large current to flow through the embedded wiring part (12b). However, when the width is too large, an occupied area is increased, which is not preferable for an electronic component that is required to be light, thin and compact. Further, it takes time to form a thick film using an electroplating method. Therefore, by having the width in the above-described range and by forming thick-film wiring part (13b) on the embedded wiring part (12b), the thickness of the wiring is increased to allow a large current to flow through.

That is, the thick-film wiring part (13b) is formed to project from the surface of the first resin insulating layer 11 and to be electrically connected to the embedded wiring part (12b). “To be electrically connected” means that, although the thick-film wiring part (13b) may be directly formed on the embedded wiring part (12b), it is also possible that the thick-film wiring part (13b) is not directly formed on the embedded wiring part (12b), but is formed on the embedded wiring part (12b) via a layer of another material, and in this case, the material is a conductive material.

As will be described later in detail in a specific example of a manufacturing method, in the present embodiment, the fine wiring pattern (12a) and the embedded wiring part (12b) are simultaneously formed from an electroplating film, and the thick-film wiring part (13b) is formed from a metal foil. When a thick metal foil is patterned by etching, side etching is also performed so that a perpendicular wiring pattern is hard to obtain. However, the thick-film wiring pattern (13c) is for a large current to flow through. Therefore, the thick-film wiring pattern (13c) is not required to be a fine pattern, and can be efficiently formed in much shorter time by etching by forming a patterning mask that takes into account an anticipated amount to be side-etched, as compared to the case where thick-film wiring pattern (13c) is formed using an electroplating method.

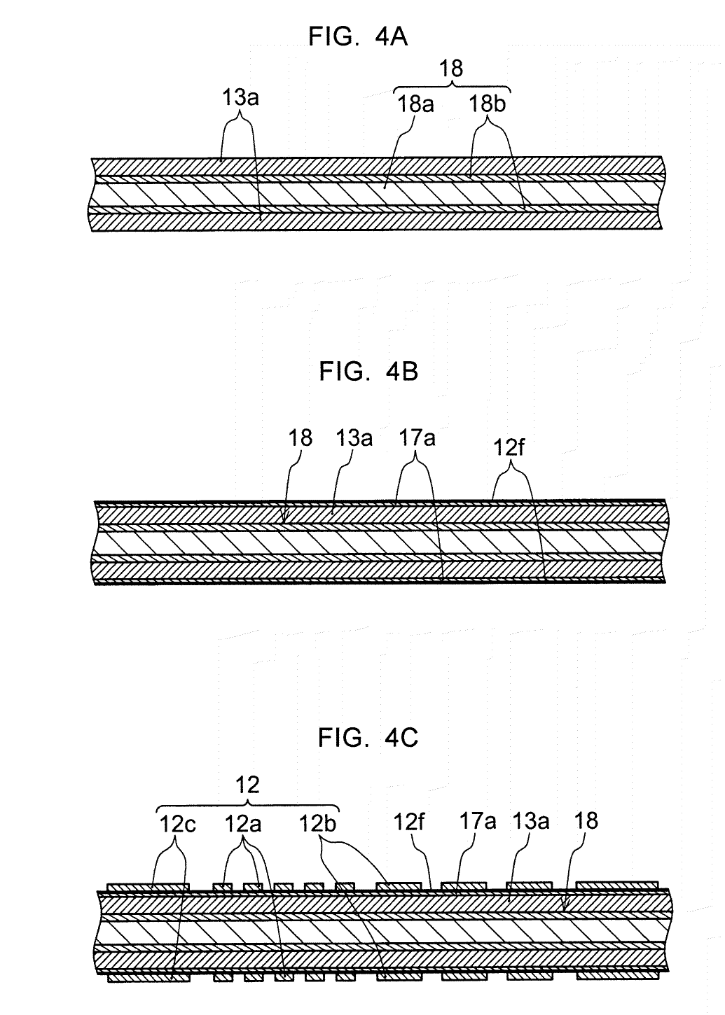

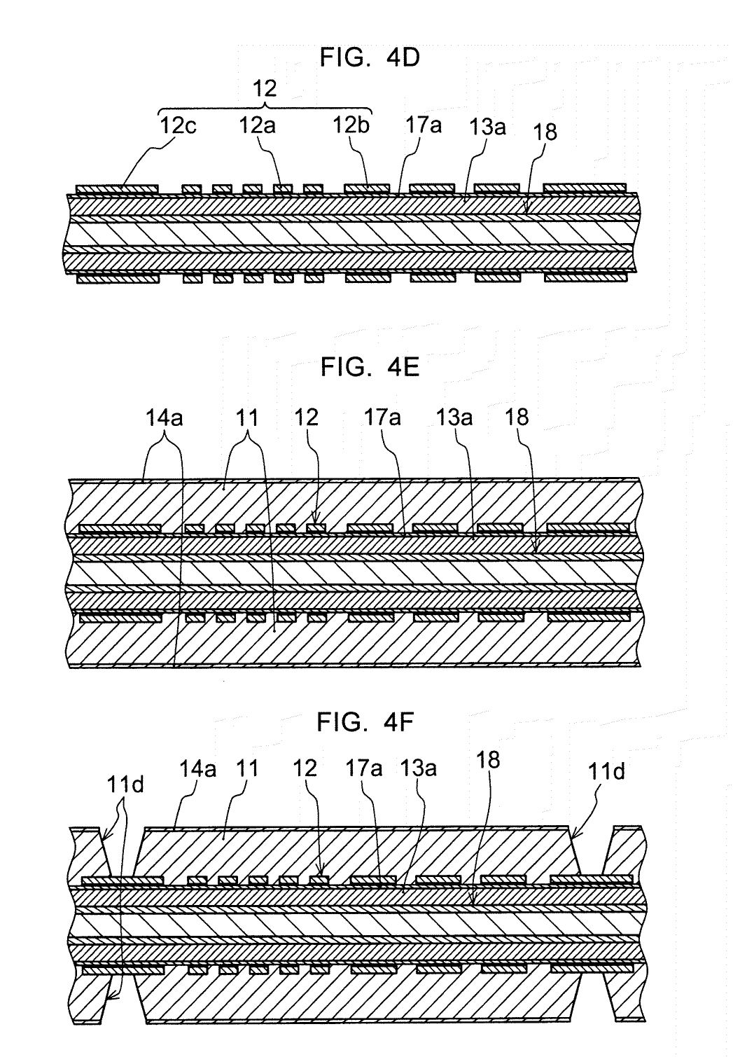

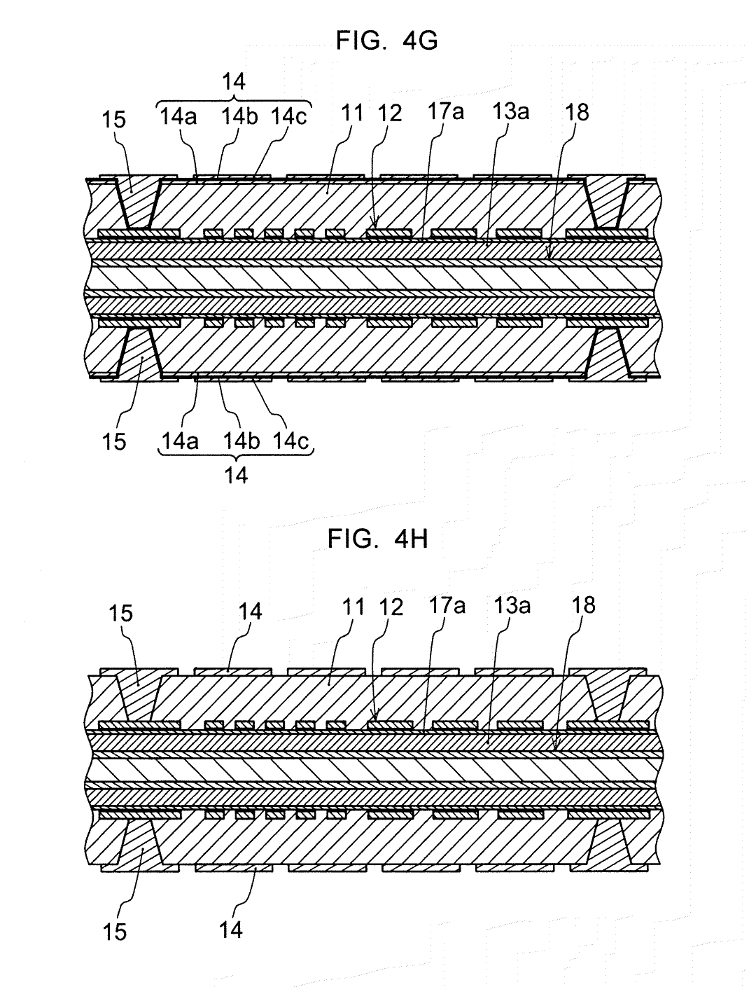

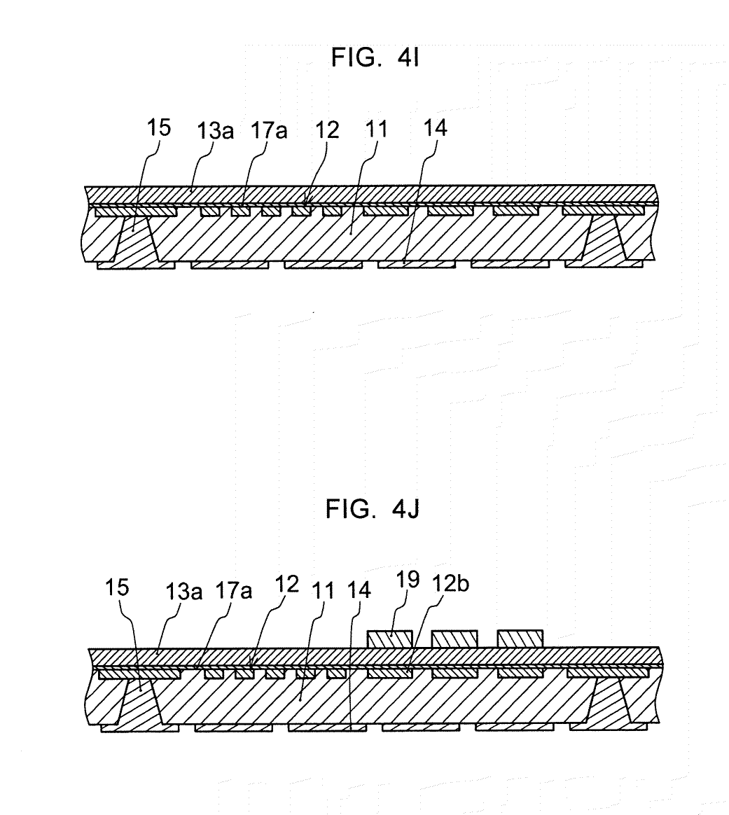

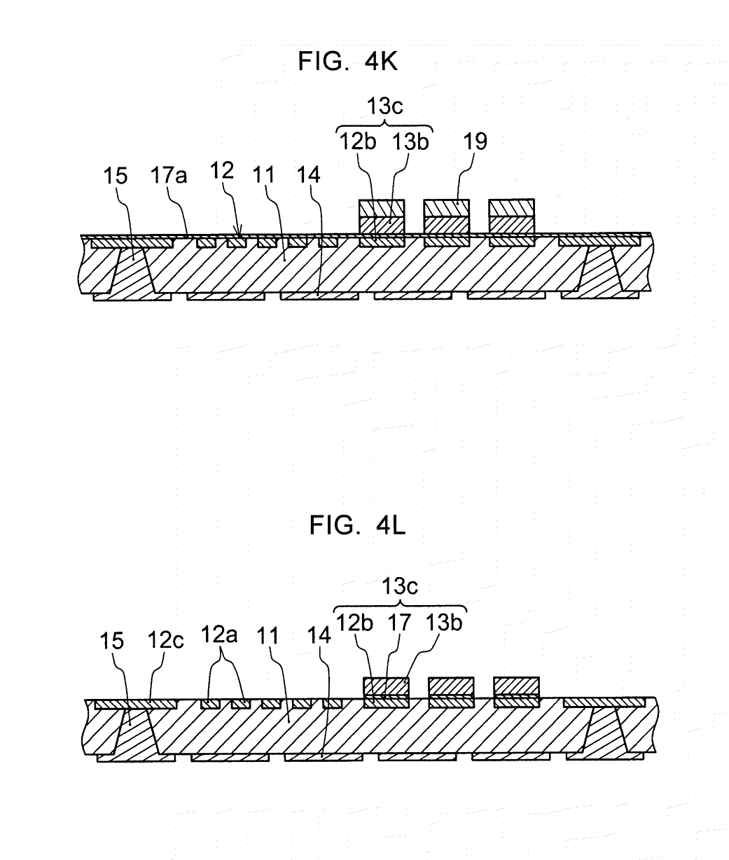

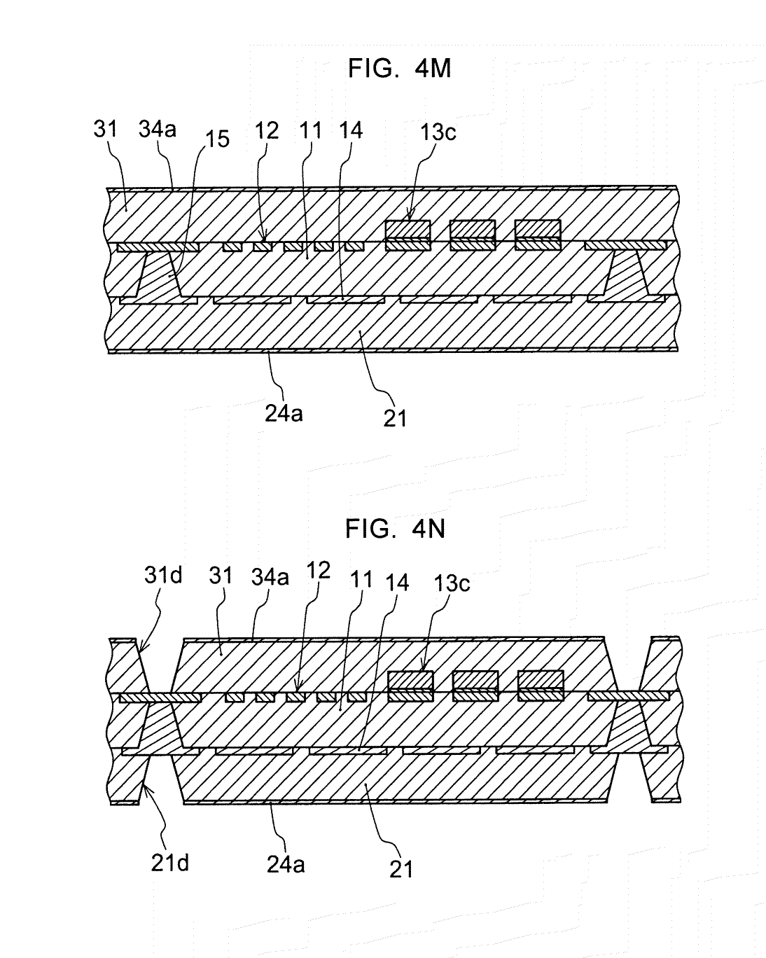

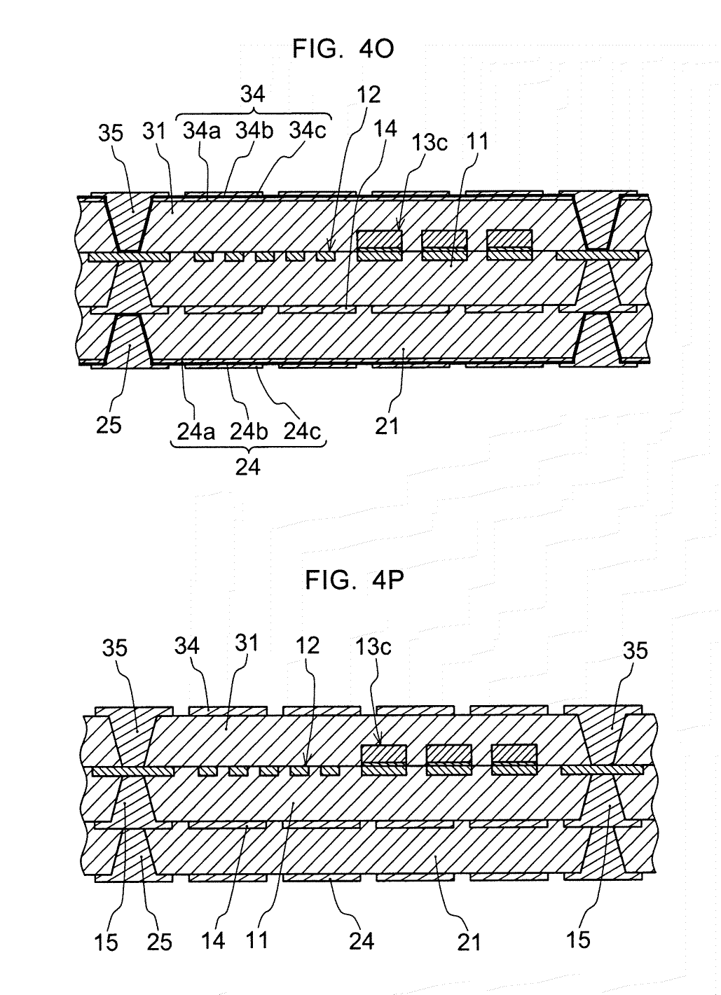

Copper has low electrical resistance and is thus commonly used for such wiring. In particular, copper is commonly used for both the embedded wiring part (12b) and the thick-film wiring part (13b) that both are wirings that are required to allow large currents to flow. Therefore, when the thick-film wiring part (13b) is formed by etching, in order to an embedded pattern 12 that includes the fine wiring pattern (12a), the embedded wiring part (12b) and another wiring pattern (12c) not to be etched, it is preferable that the barrier metal layer 17 be interposed between the embedded pattern 12 and the thick-film wiring part (13b). Therefore, between the embedded pattern 12 and a metal film (13a) (see FIG. 4B) (to be described later) for forming the thick-film wiring part (13b), the barrier metal film (17a) (see FIG. 4C) is interposed.

However, it is also possible that the barrier metal layer 17 is not provided. In this case, when etching is performed to form the thick-film wiring part (13b), since the metal film (13a) (see FIG. 4B) and the embedded pattern 12 are in contact with each other, any portion of the metal film (13a) that is to be removed must be completely removed by etching because short circuiting occurs between wirings when etching residue of the metal film (13a) remains. As a result, the embedded pattern 12 that is exposed by etching the metal film (13a) is also slightly etched and is recessed from the first surface (11a) of the first resin insulating layer 11.

In the case where such a fine wiring pattern (12a) is formed by being embedded in the first resin insulating layer 11, as will be described later in detail in a manufacturing method, the metal film (13a) (see FIG. 4B) for the thick-film wiring part (13b) is used. Therefore, a metal foil may not be a material that is particularly provided, and a metal foil having a thickness thicker than a normal metal foil which is eventually discarded may be used, without causing significant waste of material. As a result, the thick-film wiring pattern (13c) having an accurate thickness can be obtained in a short time without causing significant waste of material.

The example illustrated in FIG. 1 is an example of a printed wiring board of a four-layer structure in which, on the surfaces of the first conductor layer 13 and the second conductor layer 14 that are respectively formed on the two surfaces of the first resin insulating layer 11, the third resin insulating layer 31 and the second resin insulating layer 21 are further respectively formed. A solder resist layer 16 is formed on each of the surface of the third resin insulating layer 31 and the surface of second resin insulating layer 21, and openings (16a) are appropriately formed in the solder resist layers 16 so that the printed wiring board can be used by being connected to another electronic component, a motherboard or the like. However, it is also possible that the build-up layers that are formed by the second resin insulating layer 21 and the third resin insulating layer 31 and the like are not formed, and the solder resist layers 16 are respectively directly formed on the surfaces of the first conductor layer 13 and the second conductor layer 14.

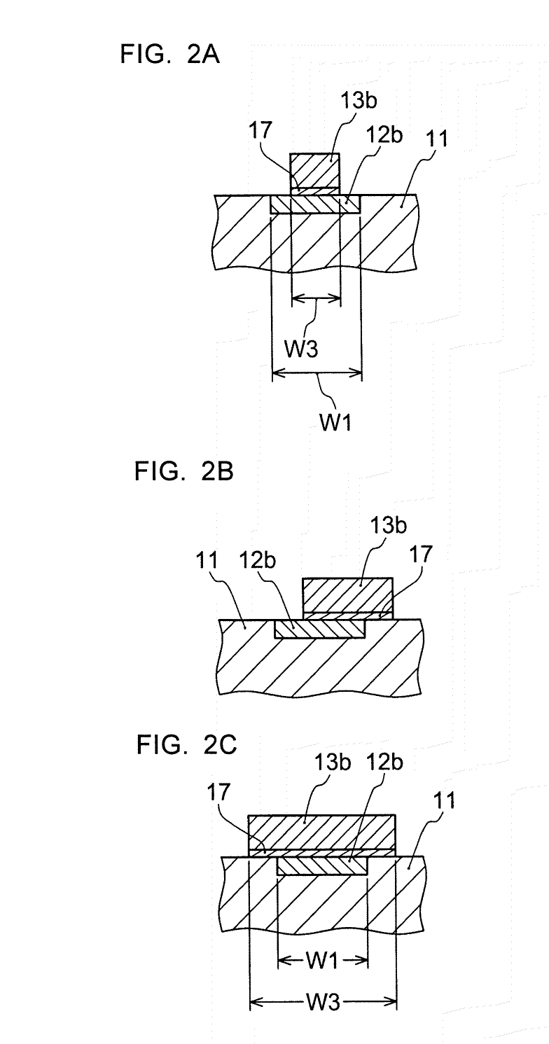

It is not necessary that the embedded wiring part (12b) and the thick-film wiring part (13b) are formed at fully matched positions. For example, as illustrated in FIG. 2A, it is also possible that the embedded wiring part (12b) is formed to be larger and the thick-film wiring part (13b) is formed to fall within the embedded wiring part (12b). That is, the example illustrated in FIG. 2A is an example in which the line width (W1) of the embedded wiring part (12b) is larger than the line width (W3) of the thick-film wiring part (13b) and the thick-film wiring part (13b) is completely within the embedded wiring part (12b). In this way, the line width (W3) of the thick-film wiring part (13b) is reduced, and it can be expected that the risk of short circuiting between adjacent wirings on the thick-film wiring part (13b) side is reduced. In FIG. 2A, the thick-film wiring part (13b) is illustrated as being vertical from a bottom surface to an upper surface. However, in practice, as will be described later, the thick-film wiring part (13b) is formed to have a wider width on the bottom side and a narrow width on the upper surface side, and it is preferable that the bottom surface have the same width as the embedded wiring part (12b) and the upper surface have a narrower width. In the example illustrated in FIG. 2A, the barrier metal layer 17 is formed to have the same width as the thick-film wiring part (13b). However, the width of the barrier metal layer 17 can be either the same width as the embedded wiring part (12b) or a completely different width.

The example illustrated in FIG. 2B illustrates a state in which the patterns of the embedded wiring part (12b) and the thick-film wiring part (13b) are out of alignment. Even when out of alignment of the patterns occurs as described above, when the out of alignment is about 20% or less relative to the line widths, it does not cause any problem. This is because only a contact portion is narrowed but as a current path there is no significant increase in resistance. Therefore, for the formation of a mask pattern for the formation of the thick-film wiring part (13b), it is not necessary to pay too much attention to strict position alignment.

The example illustrated in FIG. 2C is an example in which the line width (W3) of the thick-film wiring part (13b) is larger than the line width (W1) of the embedded wiring part (12b), and the thick-film wiring part (13b) is formed in a structure that completely covers the embedded wiring part (12b). When there is no risk of contact between adjacent wirings, that the thick-film wiring part (13b) is formed to have a large width allows a large current to flow through even when the thickness is not that much thick, and thus is preferable. When the width of the thick-film wiring part (13b) is widened as described above, a gap between adjacent thick-film wiring parts (13b) is narrowed. However, the width of the thick-film wiring part (13b) is relatively wide and even when the thick-film wiring part (13b) is side-etched to some extent, it does not cause any significant problem. Therefore, even for a gap of a narrow width, a gap can be surely formed between the wirings by etching.

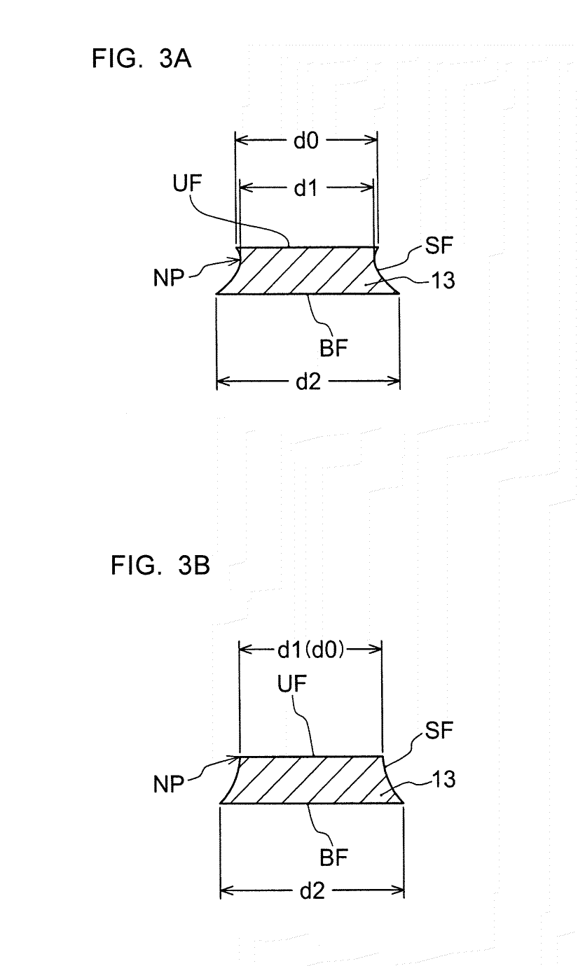

As described above, the thick-film wiring part (13b) is formed by etching the metal film (13a). However, for example, as illustrated in FIGS. 3A and 3B in each of which an enlarged cross-sectional view of the thick-film wiring part (13b) is illustrated, the thick-film wiring part (13b) is formed to have a curved side surface. Thereby, a contact area of the thick-film wiring part (13b) with the third resin insulating layer 31 or with the solder resist layer 16 is increased and thus, adhesion to each layer is improved.

That is, in a structure illustrated in FIG. 3A, the thick-film wiring part (13b) has an upper surface (UF), a lower surface (BF) on an opposite side of the upper surface, and a side surface (SF) between the upper surface and the lower surface. The side surface (SF) is curved. It is preferable that a width (d0) of the thick-film wiring part (13b) at the upper surface (UF) be smaller than a width (d2) of the thick-film wiring part (13b) at the lower surface (BF). In FIG. 3A, a thinnest portion (NP) exists between the upper surface (UF) and the lower surface (BF), and a width (d1) of the thinnest portion (NP) is narrower than the width (d0) at the upper surface (UF) and is narrower than the width (d2) at the lower surface (BF).

In the example illustrated in FIG. 3B, the width of the thick-film wiring part (13b) increases from the upper surface (UF) toward the lower surface (BF). In FIG. 3B, the thinnest portion (NP) is formed at the upper surface (UF) of the thick-film wiring part (13b), and thus d1=d0. However, also in the example illustrated in FIG. 3B, the shape of the side surface (SF) of the thick-film wiring part (13b) is not straight, but is curved. Therefore, a contact area of the thick-film wiring part (13b) with the third resin insulating layer 31 or the solder resist layer 16 is increased and thus, adhesion is improved. Such shapes can be obtained by adjusting an etching condition or the like. Therefore, by controlling the thickness and the shape of the thick-film wiring part (13b), a stress is further relaxed.

The first resin insulating layer 11 is an insulating layer that has the first surface (11a) and the second surface (11b) that is on the opposite side of the first surface (11a). The first resin insulating layer 11, for example, may be formed by impregnating a core material such as glass fiber with a resin composition that contains a filler, and may also be formed using a resin composition alone that contains a filler. Further, the first resin insulating layer 11 may be formed to be a single layer and may also be formed from multiple insulating layers. When the first resin insulating layer 11 is formed from multiple insulating layers, for example, a thermal expansion coefficient, flexibility and a thickness of the first resin insulating layer 11 can be easily adjusted. Examples of the resin include epoxy and the like. The thickness of the first resin insulating layer 11, for example, is in a range of 25-100 μm. On the first surface (11a), the first conductor layer 13 is provided. On the second surface (11b) side, the second conductor layer 14 is provided. In the example illustrated in FIG. 1, the second resin insulating layer 21 and the third resin insulating layer 31 are respectively provided on the two sides of the first resin insulating layer 11. However, the same resin insulating material as the first resin insulating layer 11 can also be used for the second and third resin insulating layers (21, 31). Further, it is also possible that different materials are selected to for the first resin insulating layer 11 and the second and third resin insulating layers.

The first conductor layer 13 is formed on the first surface (11a) side of the first resin insulating layer 11, and includes the fine wiring pattern (12a) and the thick-film wiring pattern (13c). The fine wiring pattern (12a), the embedded wiring part (12b) that is a part of the thick-film wiring pattern (13c), and the other wiring pattern (12c), are formed as the embedded pattern 12. The embedded pattern 12 is substantially flush with the first surface (11a) of the first resin insulating layer 11, and one surface of the embedded pattern 12 is exposed. As described above, when the barrier metal layer 17 is not provided, it is possible that the exposed surface of the embedded pattern 12 is recessed relative to the first surface (11a) of the first resin insulating layer 11. In this way, embedding the embedded pattern 12 in the first resin insulating layer 11 contributes to reduction in a thickness of the printed wiring board 1 and contributes to improvement in adhesion between the embedded pattern 12 and the first resin insulating layer 11. As a result, further, there is also an advantage of being able to adapt to a fine wiring pattern. A method for forming the embedded pattern 12 is not particularly limited. Preferably, the embedded pattern 12 may be an electroplating film formed by using electroplating method. When the embedded pattern 12 is an electroplating film, there is an advantage that the embedded pattern 12 is formed as a pure metal film. Copper is an example of a material with which the embedded pattern 12 is formed. Copper allows electroplating to be easily performed and has a small electrical resistance, and a corrosion problem is also unlikely to occur. The embedded pattern 12 has a thickness, for example, in a range of 3-20 μm.

As described above, the embedded pattern 12 at least includes the fine wiring pattern (12a) and the embedded wiring part (12b) that is a part of the thick-film wiring pattern (13c). For example, the embedded pattern 12 is formed by forming a resist pattern and performing plating in openings of the resist pattern. Therefore, the fine wiring pattern (12a) and the embedded wiring part (12b) are simultaneously formed and have the same thickness. However, the fine wiring pattern (12a) is formed in a very fine pattern having the line width (W2) that is smaller than the line width (W1) of the embedded wiring part (12b) and also having a narrow wiring interval. On the other hand, as described above, the embedded wiring part (12b) has the line width (W1) that is larger than the line width (W2) of the fine wiring pattern (12a), has a larger wiring interval, and does not require high fineness.

The thick-film wiring part (13b) may be formed to be a single layer and may also be formed from multiple insulating layers. When the thick-film wiring part (13b) is formed from multiple layers, examples of materials of the layers include Cu/Ni, Cu/Ti, Au/Pd/Ni, and Au/Ni. Ni or Ti that is provided as an outermost layer can function as a surface protection film. The thickness of the thick-film wiring part (13b) is determined by a required current amount. For example, the thickness of the thick-film wiring part (13b) is about 10-50 μm.

As described above, it is preferable that the barrier metal layer 17 be interposed between the embedded wiring part (12b) and the thick-film wiring part (13b). The barrier metal layer 17 is formed of a material different from those of the thick-film wiring part (13b) and the embedded pattern 12. Examples of the material include nickel, titanium and the like. The barrier metal layer 17 functions as a barrier layer so that, when the thick-film wiring part (13b) is patterned and formed from the metal film (13a) (see FIG. 4B), the embedded pattern 12 that is normally formed of the same material as that of the thick-film wiring part (13b) is not etched. In particular, as will be described later, when the thick-film wiring part (13b) becomes thick, it is difficult to precisely perform etching control. However, by providing the barrier metal layer 17, the thick-film wiring part (13b) is accurately formed without any risk of over etching the embedded pattern 12. It is sufficient for the barrier metal layer 17 to have a thickness of about a few micrometers (μm).

As described above, it is also possible that the barrier metal layer 17 is not provided. In this case, it is preferable that over etching be performed so that a portion of the metal film (13a) that is to be removed is completely removed. Therefore, as a result, the surface of the embedded pattern 12 that is exposed by removing the metal film (13a) is recessed, for example, about 1 μm relative to the first surface (11a) of the first resin insulating layer 11. Therefore, it is preferable that the embedded pattern 12 be formed thick in advance.

The second conductor layer 14 is formed projecting from the second surface (11b) of the first resin insulating layer 11. A method for forming the second conductor layer 14 is not particularly limited. Copper is an example of a material with which the second conductor layer 14 is formed. The second conductor layer 14, for example, has a thickness of about 3-20 μm. The second conductor layer 14 is illustrated as an example of a single layer in FIG. 1. However, as will be described later, for example, the second conductor layer 14 may also be formed by a metal foil and a plating film (including an electroless plating film).

The first via conductors 15 penetrate through the first resin insulating layer 11 and electrically connect the embedded pattern 12 and the second conductor layer 14. The via conductors 15 are formed by filling a conductive material in first through holes (11d) that penetrate through the second conductor layer 14 and the first resin insulating layer 11. As a material for the via conductors 15, copper is used as an example. The via conductors 15 are formed, for example, by electroplating.

In the example illustrated in FIG. 1, the build-up layers are formed that respectively include the second resin insulating layer 21 and the third conductor layer 24, and the third resin insulating layer 31 and the fourth conductor layer. However, these build-up layers can be formed using the same materials and the same methods as the above-described first resin insulating layer 11 and the second conductor layer 14 and thus the description thereof is omitted.

The solder resist layers 16 are respectively formed on the two sides, and the openings (16a) are formed in the solder resist layers 16 at portions where electrodes of another electronic component or the like are connected and at portions that are connected to a motherboard. An example of a material with which the solder resist layers 16 are formed is a thermosetting epoxy resin. The solder resist layers 16 are formed to have a thickness of, for example, about 20 μm. In the case where the build-up layers are not formed, the solder resist layers 16 are respectively formed on the surfaces of the first conductor layer 13 and the second conductor layer 14 that are respectively formed on the two surfaces of the first resin insulating layer 11. That the solder resist layers 16 that are respectively formed on the surfaces have the same thickness is because thermal expansion (contraction) and the like are balanced on the front and back sides of the printed wiring board 1 and a formation process is simple, and thus is preferable. However, depending on the thicknesses of the outermost-surface conductor layers, the solder resist layers 16 may have different thicknesses on the front and back sides.

In the above, according to the present embodiment, the printed wiring board 1 is described that includes the first conductor layer 13 that has the fine wiring pattern (12a) and the thick-film wiring pattern (13c). However, according to such a method, the fine wiring pattern (12a) is formed based on a fine resist pattern using an electroplating method, and the thick-film wiring pattern (13c) is formed by forming the thick-film wiring part (13b) on the embedded wiring part (12b) using a metal foil such a copper foil, the embedded wiring part (12b) being simultaneously formed with the fine wiring pattern (12a) using the electroplating method. The metal foil is not formed on the fine wiring pattern (12a), and thus does not require a fine pattern, and patterning can be performed in a usual etching process, so that the thick-film wiring part (13b) can be easily formed in a very short time. That is, the metal foil is provided on the entire surface of the embedded pattern 12 in which the patterns including the fine wiring pattern (12a) are formed, and the metal foil on the fine wiring pattern (12a) is completely removed. Therefore, the fine wiring pattern for which high fineness is required and the thick-film wiring pattern (13c) for a large current are simultaneously formed as wiring patterns according to purposes.

A method for manufacturing the printed wiring board illustrated in FIG. 1 is described with reference to FIG. 4A-4P.

First, as illustrated in FIG. 4A, a carrier 18 is prepared on which the metal film (13a) is provided. As the carrier 18, for example, a copper-clad laminated plate is used. However, the present invention is not limited to this. In the example illustrated in FIG. 4A, to both sides of a support plate (18a) that is formed of, for example, a prepreg, for example, the metal film (13a) with a carrier copper foil (18b) is affixed using an adhesive or using a thermal compression bonding method or the like; for example, the carrier copper foil (18b) side is affixed to the both sides of the support plate (18a). Thereby, the carrier 18 is formed. For example, the metal film (13a) is formed to have a thickness of 10-50 μm and preferably 20-40 μm, and the carrier copper foil (18b) is formed to have a thickness of 15-30 μm and preferably about 18 μm.

The carrier 18 is used as a substrate during processing of the following processes and, as will be described later, will be removed without being left as a printed wiring board. Therefore, in order for the carrier 18 to be separated from the embedded pattern 12 and the like, the metal film (13a) is provided on the surface of the carrier 18. However, the metal film (13a) is bonded to and fixed on the carrier 18 over the entire surface via an easily separable adhesive such as a thermoplastic resin or the like interposed between the metal film (13a) and the carrier 18 so that the metal film (13a) is easily separable from the carrier 18. That is, the carrier copper foil (18b) and the metal film (13a) are bonded over the entire surface by a thermoplastic resin or the like to form the metal film (13a) with the carrier copper foil (18b), and the carrier copper foil (18b) is bonded to the support plate (18a) by thermal compression bonding or the like. By being bonded by the thermoplastic resin, even when being bonded over the entire surface, the metal film (13a) and the carrier copper foil (18b) can be easily separated from each other by increasing temperature. However, without being limited to this, for example, it is also possible that the metal film (13a) and the carrier copper foil (18b) are bonded or fixed to each other over only a surrounding area. By being fixed to each other over the surrounding area, the two can be easily separated from each other by cutting the surrounding area. Therefore, the fixation in the surrounding area in this case is not limited to using the thermoplastic resin. It is desirable that there be no difference in thermal expansion and the like between the carrier 18 and the metal film (13a). Therefore, when nickel is used for the metal film (13a), it is preferable that the carrier copper foil be also formed of the same material such as a carrier nickel foil. Therefore, a release layer may be suitably provided on the surface of the carrier 18 on which the metal film (13a) is provided.

In the example illustrated in FIG. 4A, the metal film (13a) with the carrier copper foil, which is obtained by bonding the carrier copper foil (18b) and the metal film (13a) in advance using an adhesive or the like, is affixed to the support plate (18a). However, it is also possible that the metal film (13a) is bonded over the entire surface or in the surrounding area or the like to the carrier 18 that is obtained by affixing the carrier copper foil (18b) or the like to the support plate (18a). Further, an example is illustrated in which the metal film (13a) is provided on both sides of the carrier 18. This is preferable in that two printed wiring boards are manufactured at once utilizing both sides of the carrier 18 that is to be discarded. However, it is also possible that only one side of the carrier 18 is used, or different circuit patterns are formed on the two sides. In an example described below, the same circuit pattern is formed on the both sides. Therefore, although both sides are illustrated in the drawings, only one side is described, and, with regard to the other side, reference numeral symbols and description are partially omitted.

As illustrated in FIG. 4B, a barrier metal film (17a) is formed on a surface of the metal film (13a), and a metal coating (12f) is further formed on a surface of the barrier metal film (17a). As described above, the barrier metal film (17a) is for preventing the embedded pattern 12 under the metal film (13a) from being over etched and the embedded pattern 12 from becoming too thin even when the metal film (13a) vanishes when the metal film (13a) is etched and patterned. The barrier metal film (17a) is formed of a material different from those of the metal film (13a) and the embedded pattern 12. For example, a copper material may be used for the metal film (13a) and the embedded pattern 12. Therefore, it is preferable that a nickel or titanium film be used as the barrier metal film (17a), and the barrier metal film (17a) be formed using an electroplating method. The nickel film is easily oxidized. Therefore, it is preferable that a thin metal coating (12f) be formed, for example, by electroless plating after the nickel film (17a) is formed so that a resistive component is not incorporated as much as possible into the nickel film. The metal coating (12f) is formed so that a surface is kept clean and an oxide film is not formed. It is preferable that a film such as a copper coating that is stable and has a small electrical resistance be formed using other methods such as vacuum deposition. For example, by forming the metal coating (12f) such as a copper coating, electroplating is easily performed using the metal coating (12f) as a power feeding layer. The metal coating (12f) is not required. However, as described above, the nickel plating film (17a) is easily oxidized. Therefore, it is preferable that the stable metal coating (12f) be formed on the surface of the nickel plating film (17a) using an electroless plating method or vacuum deposition or the like.

As illustrated in FIG. 4C, electroplating is performed using the metal coating (12f) or the metal film (13a) as one of electrodes. That is, a resist pattern (not illustrated in the drawings) is formed on the surface of the metal coating (12f), for forming the fine wiring pattern (12a), the pattern of the embedded wiring part (12b) of the thick-film wiring pattern (13c), and the other wiring pattern (12c). On a portion where the metal coating (12f) is exposed, for example, copper plating is performed using, for example, an electrolytic copper plating method using the metal film (13a) or the metal coating (12f) as a power feeding layer on one side. There, the embedded pattern 12, as the patterns (12a-12c), is formed. Thereafter, by removing the resist pattern, the embedded pattern 12 is formed on the barrier metal film (17a) via the metal coating (12f) as illustrated in FIG. 4C. At this point, the metal coating (12f) remains. Therefore, the fine wiring pattern (12a) and the embedded wiring part (12b) are not completely separated from each other. However, for clarity, they are indicated using separate reference numeral symbols. They are collectively referred to as the embedded pattern 12.

As illustrated in FIG. 4D, the resist pattern is removed, and the exposed metal coating (12f) that is formed from electroless plating and the like is removed by etching. The metal coating (12f) is very thin, and thus is removed by subjecting the entire surface thereof to light etching without masking the surface of the embedded pattern 12.

As illustrated in FIG. 4E, the first resin insulating layer 11 and a metal foil (14a) that becomes a part of the second conductor layer 14 are laminated on the embedded pattern 12 and on the exposed surface of the barrier metal film (17a). For the lamination of the first resin insulating layer 11 and the metal foil (14a), the bonding may be performed by applying pressure and heat.

As illustrated in FIG. 4F, the first through holes (11d) are formed. As a method for forming the through holes (11d), a method of laser irradiation is used. That is, the through holes (11d) are formed at portions where the embedded pattern 12 and the second conductor layer 14 that are provided on the two sides of the first resin insulating layer 11 are connected, and are processed by irradiating CO2 laser or the like from the surface of the metal foil (14a).

As illustrated in FIG. 4G, a metal coating (14b) such as an electroless plating film is formed in the first through holes (11d) and on the metal foil (14a). Next, for example, by electroplating, the first via conductors 15 are formed, and a layer of the electroplating film (14c) is formed on the surface of the metal coating (14b). The electroplating film (14c) is formed by performing electroplating using a resist mask that is formed, for example, by removing a portion of a resist film coated over an entire surface to match the pattern of the second conductor layer 14, and thereafter removing the resist mask. The second conductor layer 14 is formed by the metal foil (14a), the metal coating (14b) and the electroplating film (14c). However, at this point, the metal foil (14a) and the metal coating (14b) are still connected and thus a complete pattern is still not formed.

As illustrated in FIG. 4H, the metal coating (14b) and the metal foil (14a) are patterned and the completely patterned three-layer second conductor layer 14 is formed. Since the metal coating (14b) and the metal foil (14a) are thin, the metal coating (14b) and the metal foil (14a) can be removed by etching the entire surface without using a mask.

As illustrated in FIG. 4I, the carrier 18 is removed. In FIG. 4I, for clarity of the description, only the upper side of the carrier 18 illustrated in FIG. 4H is illustrated with up and down being inverted in the drawing. As described above, the carrier 18 (carrier copper foil (18b)) and the metal film (13a) are fixed to each other by an easily separable adhesive or the like such as a thermoplastic resin, and thus can be easily separated from each other by peeling one from the other in a state in which the temperature has been raised, and a surface of the metal film (13a) that is in contact with the carrier copper foil (18b) is exposed.

As illustrated in FIG. 4J-4L, the metal film (13a) is patterned, and the thick-film wiring part (13b) is formed (see FIG. 4L). In order to pattern the thick-film wiring part (13b), as illustrated in FIG. 4J, a resist mask 19 is formed matching the position of the embedded wiring part (12b) of the embedded pattern 12.

As illustrated in FIG. 4K, the metal film (13a) is etched. The metal film (13a) remains only on the lower side of the resist mask 19, and thus the thick-film wiring part (13b) is formed. For example, in the case where the metal film (13a) is formed with a copper foil, the etching is performed using a copper etching solution. When the copper film (metal film (13a)) is etched and the barrier metal film (17a) is exposed, the barrier metal film (17a) is not etched. Therefore, only the metal film (13a) is patterned. During the etching, the metal film (13a) below the resist mask 19 is also side-etched to some extent and the side surface is in a curved shape as illustrated in FIGS. 3A and 3B.

As illustrated in FIG. 4L, the barrier metal film (17a) is etched. However, only the exposed portion of the barrier metal film (17a) is etched and removed by using an etching solution that only etches the barrier metal film (17a), but does not etch the thick-film wiring part (13b) and the fine wiring pattern (12a). As a result, the barrier metal layer 17 remains only between the thick-film wiring part (13b) and the embedded wiring part (12b). In other parts, the first resin insulating layer 11 and the embedded pattern 12 are flush with each other and are exposed. The resist mask 19 is removed before or after the etching of the barrier metal film (17a).

As illustrated in FIG. 4M, using the same method as in the above-described process illustrated in FIG. 4E, on the surface on which the second conductor layer 14 is formed, the second resin insulating layer 21 and the third metal foil (24a) that will become a part of the third conductor layer 24 are laminated; and further also on the embedded pattern 12 side, the third resin insulating layer 31 and the fourth metal foil (34a) that will become a part of the fourth conductor layer 34 are laminated. The lamination of the layers is performed in the same way as described above by using a prepreg material and the like and by applying heat and pressure.

As illustrated in FIG. 4N, second through holes (21d) are formed in the second resin insulating layer 21; and third through holes (31d) are formed in the third resin insulating layer 31. The second and third through holes (21d, 31d) are formed using a method that is the same as the above-described method illustrated in FIG. 4F, in which laser irradiation is used. That is, the second and third through holes (21d, 31d) are respectively formed at portions where the second conductor layer 14 and the third conductor layer 24 (that are respectively provided on two sides of the second resin insulating layer 21) are connected to each other and at portions where the first conductor layer 13 (embedded pattern 12) and the fourth conductor layer 34 (that are respectively provided on two sides of the third resin insulating layer 31) are connected to each other, and are processed by respectively irradiating CO2 laser or the like from surfaces of the third metal foil (24a) and the fourth metal foil (34a).

Similar to FIG. 4G, a third metal coating (24b) and a fourth metal coating (34b), which are electroless plating films or the like, are respectively formed in the second through holes (21d) and on the third metal foil (24a), and in the third through holes (31d) and on the fourth metal foil (34a). As illustrated in FIG. 4O, for example, by electroplating, second via conductors 25 and third via conductors 35 are formed, and a layer of the third electroplating film (24c) and a layer of the fourth electroplating film (34c) are respectively formed on the surface of the third metal coating (24b) and on the surface of the fourth metal coating (34b). The third electroplating film (24c) and the fourth electroplating film (34c) can be formed by forming resist masks having openings that match the patterns of the third conductor layer 24 and the fourth conductor layer 34, performing electroplating in the openings, and thereafter removing the resist masks. The third conductor layer 24 is formed by the third metal foil (24a), the third metal coating (24b) and the third electroplating film (24c); and the fourth conductor layer 34 is formed by the fourth metal foil (34a), the fourth metal coating (34b) and the fourth electroplating film (34c).

Similar to FIG. 4H, exposed portions of the third metal coating (24b), the fourth metal coating (34b), the third metal foil (24a) and the fourth metal foil (34a) are etched, and the three-layer third conductor layer 24 and the three-layer fourth conductor layer 34 are respectively formed. Since the third metal coating, the fourth metal coating (34b), the third metal foil (24a) and the fourth metal foil (34a) are all thin, it is possible that only the exposed portions are removed by etching the entire surface without using a mask. As a result, as illustrated in FIG. 4P, the build-up layers are respectively formed on the first conductor layer 13 (embedded pattern 12) side of the first resin insulating layer 11 and on the second conductor layer 14 side of the first resin insulating layer 11.

When build-up layers and the like are further laminated, by repeating the above-described processes of FIG. 4M-4P, a desired multilayer printed wiring board can be obtained.

Next, the solder resist layers 16 are applied to the exposed surface sides of the third and second resin insulating layers (31, 21) so as to protect the exposed surfaces of the fourth conductor layer 34 and the third conductor layer 24. The openings (16a) are formed so that connecting parts for an electronic component or the like are exposed or connecting parts for a motherboard (not illustrated in the drawings) or the like are exposed. Thereby, the printed wiring board 1 as illustrated in FIG. 1 is obtained.

Although not illustrated in the drawings, the exposed portions of the wirings that connect to an electronic component and the like are subjected to a surface treatment using coatings such as OSP, Ni/Au, Ni/Pd/Au, Sn, and the like.

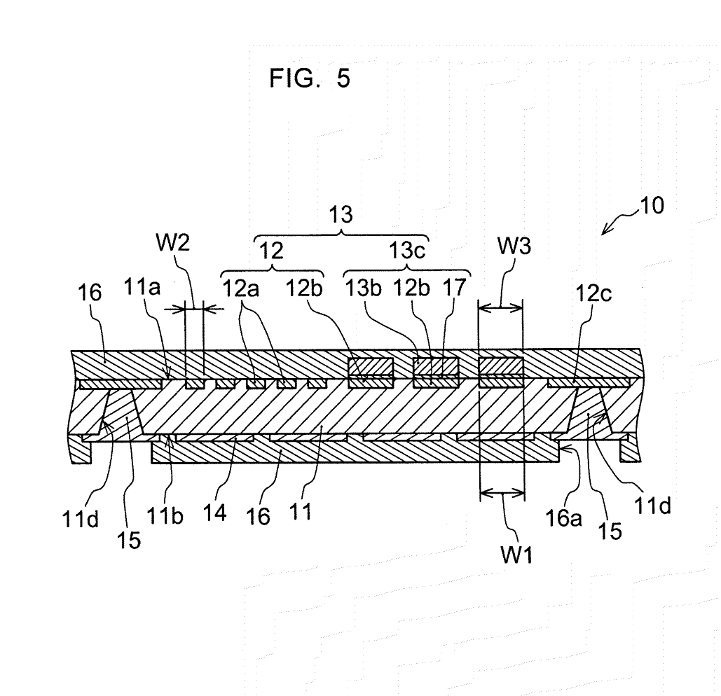

Further, in the case where the build-up layers are not formed, by forming the solder resist layers 16 on both sides in the above-described state illustrated in FIG. 4L, a printed wiring board 10 as illustrated in FIG. 5 is obtained.

In the above-described example, at the point when the second conductor layer 14 is formed, the carrier 18 is peeled off and the first conductor layer 13 is formed. However, in the case where a build-up layer is formed only on the second conductor layer 14 side, or in the case where more build-up layers are formed on the second conductor layer 14 side than on the first conductor layer 13 side, it is also possible that, following the above-described process of FIG. 4H, without peeling off the carrier 18, a build-up layer is further formed on the second conductor layer 14.

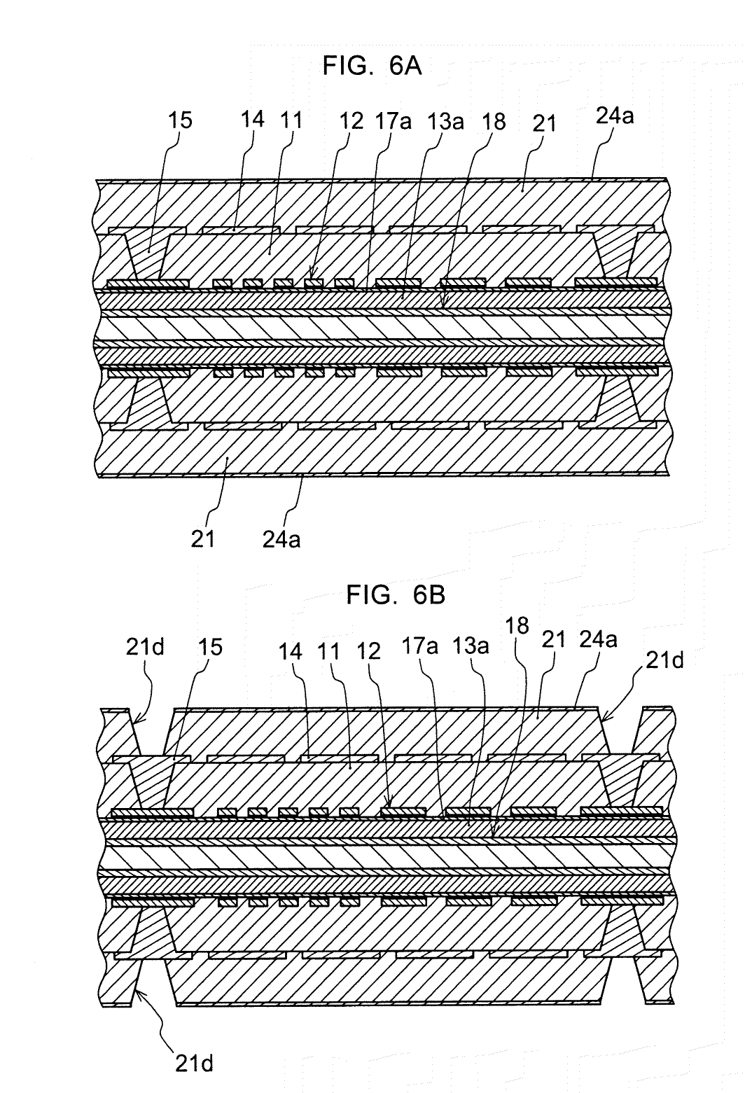

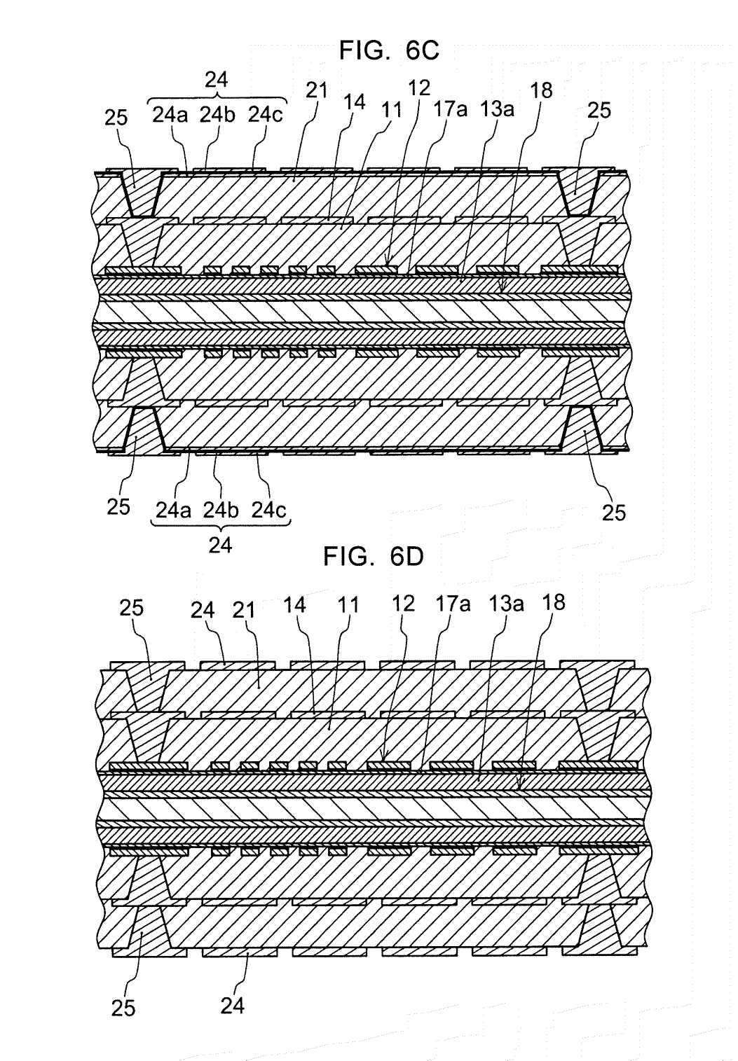

An example of this is illustrated in FIG. 6A-6D. This is the same as the above-described process illustrated in FIG. 4M-4P in which the second resin insulating layer 21 and the third conductor layer 24 are formed, and the same reference numeral symbols are used and the description is omitted. By using this manufacturing method, two same printed wiring boards are simultaneously formed on the two sides of the carrier 18. When more build-up layers are formed, by further repeating this process, a desired number of build-up layers are formed. After the desired build-up layers are formed, as illustrated in the above-described FIG. 4I, the carrier 18 is peeled off. By performing the above-described process of FIG. 4J-4L, the first conductor layer 13 having the fine wiring pattern (12a) and the thick-film wiring pattern (13c) is formed. On the surface side of the first conductor layer 13, before the solder resist layer 16 is provided, it is also possible that, in the same way as described above, a build-up layer is further laminated.

As described above, according to the present embodiment, even in the printed wiring board 1 that includes the first conductor layer 13 in which the fine wiring pattern (12a) and the thick-film wiring pattern (13c) coexist, the fine wiring pattern (12a) is formed as an embedded wiring using an electroplating film; and further, a part of the thick-film wiring pattern (13c), as the embedded wiring part (12b), is formed simultaneously with the fine wiring pattern (12a) from the electroplating film, and the other part of the thick-film wiring pattern (13c) is formed by patterning a metal foil. Therefore, the fine wiring pattern (12a) is formed as a very finely processed precise wiring pattern; and for the thick-film wiring pattern (13c), although dimensional precision is reduced due to etching, a thick film with a uniform thickness can be formed in a short time. As a result, the printed wiring board 1 that satisfies the characteristics of the both is obtained.

On the other hand, as is clear from the above-described manufacturing method, the thick-film wiring part (13b) is formed by only patterning the metal film (13a) that is formed on the surface of the carrier 18. In a printed wiring board in which the thick-film wiring part (13b) is not provided, when a fine wiring pattern is formed as an embedded wiring, a metal film is a base layer for peeling the embedded pattern from a carrier and is conventionally completely removed. In the above embodiment, to form the thick-film wiring part (13b), it is preferable that the metal film (13a) be used that is slightly thicker than a metal film that is merely used as a base layer. This does not necessarily mean that the number of processes is increased. The thick-film wiring part (13b) can be easily formed by only allowing a portion of the metal film (13a) to remain. In other words, although a patterning process is added, without the need of adding any additional material, the thick-film wiring part (13b) can be effectively formed.

The embodiment illustrated in FIG. 1 is an example in which one build-up layer is formed on each of both sides of the core substrate (first resin insulating layer 11) in which the fine wiring pattern (12a) and the thick-film wiring pattern (13c) are formed. However, as illustrated in FIG. 5, it is also possible to have a printed wiring board in which a build-up layer is not formed as all. As described above, it is also possible to have a printed wiring board in which a build-up layer is formed only on one of the two sides. Further, it is also possible that two or more build-up layers are formed on one side or on both sides.

By embedding a conductor circuit pattern in an insulating substrate, even for a fine wiring pattern, an adhesive force between the insulating substrate and the wiring pattern may be made strong. However, in such a structure, only a wiring pattern having one kind of film thickness can be formed. On the other hand, depending on a wiring, there are cases where a thick-film wiring called a thick-copper pattern that allows a large current to flow is required.

A printed wiring board according to an embodiment of the present invention has a fine wiring pattern and a thick-film wiring pattern which coexist such that the fine wiring pattern is finely formed and the thick-film wiring pattern is formed sufficiently thick, both at a uniform thickness, and according to another embodiment of the present invention is a method for manufacturing such a printed wiring board.

A printed wiring board according to an embodiment of the present invention allows a thick-film wiring pattern to be manufactured in a short time while having accuracy of a fine wiring pattern, and another embodiment of the present invention is a method for manufacturing such a printed wiring board.

A printed wiring board according to an embodiment of the present invention includes a first resin insulating layer that has a first surface and a second surface that is on an opposite side of the first surface; and a first conductor layer in which a fine wiring pattern and a thick-film wiring pattern coexist, the fine wiring pattern being embedded on the first surface side of the first resin insulating layer, only one surface of the fine wiring pattern being exposed, and the thick-film wiring pattern including an embedded wiring part that is embedded in the first resin insulating layer and a thick-film wiring part that is provided on the embedded wiring part directly or via another conductive layer and is formed to project from the first resin insulating layer. A line width of the embedded wiring part of the thick-film wiring pattern is larger than a line width of the fine wiring pattern.

A method for manufacturing a printed wiring board according to an embodiment of the present invention includes: providing a metal film on a carrier that has a carrier metal; forming at least a fine wiring pattern and an embedded wiring part of a thick-film wiring pattern on the metal film directly or via another layer; forming a first resin insulating layer on the metal film such that the fine wiring pattern and the embedded wiring part are each embedded with one surface being exposed; removing the carrier to expose one surface of the metal film; and forming a thick-film wiring pattern by etching the metal film such that a portion of the metal film remains and a thick-film wiring part is formed on the embedded wiring part, thereby forming a first conductor layer that includes the fine wiring pattern and the thick-film wiring pattern. A line width of the embedded wiring part of the thick-film wiring pattern is larger than a line width of the fine wiring pattern; the fine wiring pattern and the embedded wiring part are formed of an electroplating film; and the thick-film wiring part is formed of a metal foil.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a resin insulating layer; and
a first conductor layer comprising a fine wiring pattern and a thick-film wiring pattern, the fine wiring pattern being embedded in the resin insulating layer such that the fine wiring pattern has an exposed surface exposed on a first surface of the resin insulating layer, the thick-film wiring pattern comprising an embedded wiring portion and a thick-film wiring portion such that the embedded wiring portion is embedded in the resin insulating layer and the thick-film wiring portion is projecting from the first surface of the resin insulating layer,
wherein the embedded wiring portion of the thick-film wiring pattern has a line width which is greater than a line width of the fine wiring pattern.

2. A printed wiring board according to claim 1, wherein the thick-film wiring pattern is formed such that the thick-film wiring portion is formed directly on the embedded wiring portion.

3. A printed wiring board according to claim 1, wherein the thick-film wiring pattern comprises the embedded wiring portion, a conductor layer portion and the thick-film wiring portion formed such that the conductive layer portion is interposed between the thick-film wiring portion and the embedded wiring portion.

4. A printed wiring board according to claim 1, wherein the thick-film wiring pattern is formed such that the thick-film wiring portion has an upper end surface having a line width which is smaller than the line width of the embedded wiring portion.

5. A printed wiring board according to claim 1, wherein the thick-film wiring pattern is formed such that the thick-film wiring portion has a curved side surface.

6. A printed wiring board according to claim 1, wherein the thick-film wiring pattern is formed such that the thick-film wiring portion is formed within the line width of the embedded wiring portion.

7. A printed wiring board according to claim 1, wherein the thick-film wiring pattern is formed such that the thick-film wiring portion is formed out of alignment with the embedded wiring portion with respect to a line width direction.

8. A printed wiring board according to claim 1, wherein the thick-film wiring pattern is formed such that the thick-film wiring portion has a width which is greater than the line width of the embedded wiring portion and is entirely covering the embedded wiring portion in a line width direction.

9. A printed wiring board according to claim 1, wherein the thick-film wiring pattern is formed such that the thick-film wiring portion has a line width which is different from the line width of the embedded wiring portion.

10. A printed wiring board according to claim 1, wherein the fine wiring pattern and the embedded wiring portion of the thick-film wiring pattern comprise an electroplating film, and the thick-film wiring portion of the thick-film wiring pattern comprises a metal foil.

11. A printed wiring board according to claim 1, wherein the fine wiring pattern is formed such that the exposed surface of the fine wiring pattern is recessed with respect to the first surface of the resin insulating layer, and the embedded wiring portion of the thick-film wiring pattern has a recessed surface portion recessed with respect to the first surface of the resin insulating layer such that the recessed surface portion does not have the thick-film wiring portion formed thereon.

12. A printed wiring board according to claim 3, wherein the conductor layer portion of the thick-film wiring pattern is a barrier metal layer made of material which is different from material forming the fine wiring pattern, material forming the embedded wiring portion of the thick-film wiring pattern, and material forming the thick-film wiring portion of the thick-film wiring pattern.

13. A printed wiring board according to claim 12, wherein the barrier metal layer is formed such that the barrier metal layer is extending beyond a lower surface of the thick-film wiring portion.

14. A printed wiring board according to claim 12, wherein the thick-film wiring portion and embedded wiring portion of the thick-film wiring pattern comprise copper, and the barrier metal layer of the thick-film wiring pattern comprises one of nickel and titanium.

15. A printed wiring board according to claim 1, wherein the thick-film wiring portion of the thick-film wiring pattern has a thickness which is at least 10 μm.

16. A printed wiring board according to claim 1, further comprising:
a second conductor layer formed on the resin insulating layer such that the second conductor layer is formed projecting on a second surface of the resin insulating layer on an opposite side with respect to the first surface;
a via conductor formed through the resin insulating layer such that the via conductor is electrically connecting the first conductor layer and the second conductor layer; and
at least one buildup layer formed on at least one of the first surface and second surface of the resin insulating layer.

17. A printed wiring board according to claim 1, further comprising:
a second conductor layer formed on the resin insulating layer such that the second conductor layer is formed projecting on a second surface of the resin insulating layer on an opposite side with respect to the first surface;
a via conductor formed through the resin insulating layer such that the via conductor is electrically connecting the first conductor layer and the second conductor layer;
a first solder resist layer formed on the first surface of the resin insulating layer such that the first solder resist layer is covering the first conductor layer; and
a second solder resist layer formed on the second surface of the resin insulating layer such that the second solder resist layer is covering the second conductor layer.

18. A method for manufacturing a printed wiring board, comprising:
forming a metal film on a carrier having a carrier metal such that the metal film is formed on the carrier metal;
forming a fine wiring pattern and an embedded wiring portion of a thick-film wiring pattern on the metal film;
forming a resin insulating layer on the metal film such that the fine wiring pattern and the embedded wiring portion are embedded in the resin insulating layer;
removing the carrier from the metal film such that a surface of the metal film is exposed; and
etching the metal film such that a portion of the metal film forms a thick-film wiring portion on the embedded wiring portion, the thick-film wiring pattern comprising the embedded wiring portion and the thick-film wiring portion is formed, and a first conductor layer comprising the fine wiring pattern and the thick-film wiring pattern is formed,
wherein the forming of the fine wiring pattern and the embedded wiring portion comprises forming the fine wiring pattern and the embedded wiring portion such that the embedded portion has a line width which is greater than a line width of the fine wiring pattern.

19. A method for manufacturing a printed wiring board according to claim 18, wherein the forming of the fine wiring pattern and the embedded wiring portion comprises applying electroplating such that the fine wiring pattern and the embedded wiring portion comprise an electroplating film, and the forming of metal film on the carrier comprises placing a metal foil on the carrier metal of the carrier such that the metal film comprising the metal foil is formed on the carrier metal of the carrier.

20. A method for manufacturing a printed wiring board according to claim 18, further comprising:
forming a conductor layer portion on the metal film prior to the forming of the fine wiring pattern and the embedded wiring portion,
wherein the etching of the metal film comprises forming the thick-film wiring pattern comprising the embedded wiring portion, the conductor layer portion and the thick-film wiring portion such that the conductive layer portion is interposed between the thick-film wiring portion and the embedded wiring portion.
